(19) United States
(12) Patent Application Publication
(10) Pub. No.: US 2022/0365736 A1
(43) Pub. Date: Nov. 17, 2022

(54) ELECTRONIC DISPLAY

(71) Applicant: CREEDON TECHNOLOGIES HK LIMITED, Sheung Wan (HK)

(72) Inventors: Mark Creedon Palfreeman, Mid-Levels (HK); Marcin Wojciech Dudar, Ma Wan (HK); So Sum Tang, Shau Kei Wan (HK)

(73) Assignee: CREEDON TECHNOLOGIES HK LIMITED, Sheung Wan (HK)

(21) Appl. No.: 17/317,097

(22) Filed: May 11, 2021

(51) Int. Cl. G06F 3/14; H04R 1/02; H04R 1/08; G10L 25/51; G06F 3/16; G06F 3/041; H05K 7/20; H05K 5/02

(52) U.S. Cl. CPC G06F 3/14; H04R 1/028; H04R 1/08; G10L 25/51; G06F 3/16; G06F 3/041; H05K 7/20954; H05K 7/20127; H05K 5/0234; H04R 2499/15

(57) ABSTRACT

An electronic display includes a body, an electronic display panel supported by the body, a screen for displaying digital content, and an electronic operating circuit provided in the body and adapted to process said digital content and control the screen to display said digital content. The body includes a vent disposed at least partially around a periphery of the body. The vent is configured to be in communication with the ambient for dissipation of heat generated by the electronic operating circuit, and to be engageable with a stand for the latter to support the body on a surface.

### TECHNICAL FIELD

The invention relates to an electronic display.

### BACKGROUND

Digital photo frames typically include a stand, e.g. a strut back, coupled to and pivotably extendable relative to the back of the body of the photo frame, for supporting the body of the photo frame on a horizontal surface, only when the stand is fully extended. This limits the viewing angle of the screen of the photo frame to a single, fixed viewing angle. Further, in the cases where the digital photo frame includes a touch screen, the strut backs with a single contact point with the body of the photo frame and a small footprint may not be sufficient to withstand the force the user exerts on the screen when touching the screen.

### SUMMARY

The present invention provides an electronic display including a body, an electronic display panel supported by the body and comprising a screen for displaying digital content, and an electronic operating circuit provided in the body and adapted to process said digital content and control the screen to display said digital content. The body includes a vent disposed at least partially around a periphery of the body. The vent is configured to be in communication with the ambient for dissipation of heat generated by the electronic operating circuit, and to be engageable with a stand for the latter to support the body on a surface.

In one embodiment, the vent is disposed around the entire periphery of the body.

In one embodiment, the vent is disposed continuously around the entire periphery of the body.

In one embodiment, the vent is disposed at regular intervals around the entire periphery of the body.

In one embodiment, the vent is configured to engage with the stand for supporting the body in a first orientation and a different second orientation.

In one embodiment, the vent is disposed at at least two, first and second portions of the periphery of the body, with which first and second portions the stand is engageable to support the body in the first orientation and the second orientation respectively, the first and second orientations being transverse to each other.

In one embodiment, the vent includes a groove in communication with the ambient.

In one embodiment, the groove is engageable with the stand.

In one embodiment, the vent further includes a plurality of through-holes, with adjacent through-holes of each pair being separated by a respective spacer.

In one embodiment, the spacers extend across opposite sides of the groove to form a said through-hole between adjacent spacers of each pair, the through-holes providing communication between interior of the body and the ambient.

In one embodiment, the electronic operating circuit includes at least one speaker for playing and emitting an audio component of said digital content through the vent.

In one embodiment, said at least one speaker is located proximate to the vent.

In one embodiment, the electronic operating circuit includes at least one microphone for receiving an audio signal through the vent to control operation of the electronic display.

In one embodiment, said at least one microphone is located proximate to the vent.

In one embodiment, the electronic operating circuit is adapted to control the electronic display when said received audio signal matches a predetermined condition.

In one embodiment, the predetermined condition comprises determination of said received audio signal including instructions to modify a setting of the electronic display.

In one embodiment, the predetermined condition comprises determination of a sound pressure level of said received audio signal reaching a predetermined threshold.

In one embodiment, the electronic operating circuit is adapted to control the electronic display to enter a sleep mode in response to determining that said sound pressure level is at or below said predetermined threshold.

In one embodiment, the screen is touch-sensitive.

In one embodiment, the electronic display further includes a said stand for supporting the body on a surface, at an acute angle thereto.

In one embodiment, the stand comprises a projection insertable into the vent for engagement with the vent.

In one embodiment, the stand comprises an upper part for contact with a back of the body and a lower part coupled to the upper part and configured to be engageable with the vent.

In one embodiment, the lower part of the stand includes a or the projection for engagement with the vent, the projection having a width that extends along a portion of the periphery of the body, with which portion the projection engages.

In one embodiment, the lower part of the stand is oriented transversely to the upper part.

In one embodiment, the lower part of the stand is extendable from the upper part for adjusting the angle of the body relative to the surface.

In one embodiment, the stand includes inter-engageable elements on the upper and lower parts of the stand for engagement to maintain the extent to which the lower part extends from the upper part and in turn the angle of the body relative to the surface.

In one embodiment, the inter-engageable elements comprise a protrusion and a row of recesses on the upper and lower parts of the stand, with one of which recesses the protrusion is engageable to maintain the angle of the body relative to the surface.

In one embodiment, the upper part of the stand includes a frictional gripping element for contact with the back of the body.

In one embodiment, the upper part and the lower part of the stand are separable apart.

### BRIEF DESCRIPTION OF THE DRAWINGS

Embodiments of the invention will now be described, by way of example, with reference to the accompanying drawings, in which:

FIG. 1 is a bottom perspective view of an electronic display in accordance with one embodiment of the invention;

FIG. 2 is a rear plan view of the body of the electronic display of FIG. 1, with portions removed to illustrate the electronic operating circuit and the speakers;

FIG. 3 is a rear perspective view of the body of the electronic display of FIG. 1;

FIG. 4 is a cross-sectional view of the body of the electronic display of FIG. 1, with portions removed to illustrate the through-holes of the vent;

FIG. 5 is an enlarged cross-sectional view of the body of the electronic display of FIG. 1;

FIG. 6A is a rear perspective view of the electronic display of FIG. 1 in a first orientation;

FIG. 6B is a rear perspective view of the electronic display of FIG. 1 in a second orientation;

FIG. 7 is a perspective view of the stand of the electronic display of FIG. 1;

FIG. 8 is a partial exploded view of the stand of FIG. 7, with portions removed;

FIG. 9A is a side view of the electronic display of FIG. 1; and

FIG. 9B is an enlarged cross-sectional view of a portion of the electronic display of FIG. 9A, illustrating the engagement between the stand and the body of the electronic display.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. Terms of degree, such as “substantially” or “approximately” are understood by those of ordinary skill to refer to reasonable ranges outside of the given value, for example, general tolerances associated with manufacturing, assembly, and use of the described embodiments.

The use of “including”, “comprising”, or “having” and variations thereof herein is meant to encompass the items listed thereafter and equivalents thereof as well as additional items. Unless specified or limited otherwise, the terms “mounted”, “connected”, “supported”, and “coupled” and variations thereof are used broadly and encompass both direct and indirect mountings, connections, supports, and couplings. Further, “connected” and “coupled” are not restricted to physical or mechanical connections or couplings.

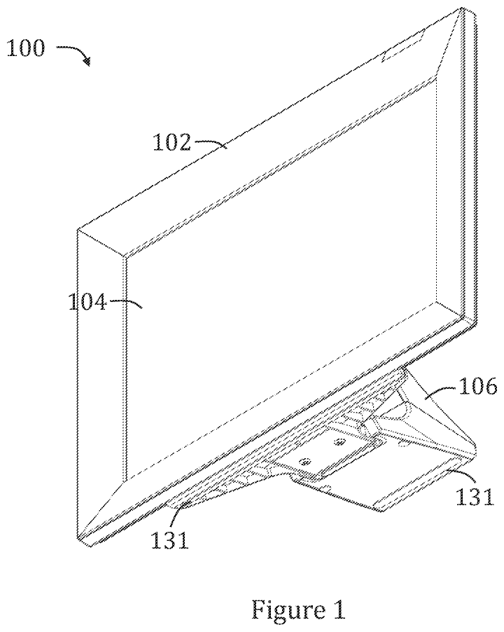

FIGS. 1 to 9B show an electronic display embodying the invention, which may be used for displaying digital content, such as still images, video images and sound. Preferably and as illustrated, the electronic display is an electronic photo frame 100. The photo frame 100 is preferably a smart photo frame that is capable of performing autonomous operations and connecting to other devices over a wired connection or a wireless connection for data exchange.

Referring initially to FIG. 1, the photo frame 100 includes a body 102, an electronic display panel supported by the body 102 and having a screen 104 for displaying digital content, and a stand 106 for supporting the body 102 on a surface, often a horizontal surface such as a table top.

The screen 104 is encircled by the body 102 in a way that the screen 104 is secured by the body 102. The screen 104 may be a liquid-crystal display (LCD). Preferably, in-plane switching (IPS) technology is utilized for the screen 104 for providing more consistent and accurate colour reproductions compared to conventional LCDs. More preferably, and as is the case, the screen 104 is touch-sensitive, allowing the user to interact with the photo frame 100.

The body 102 may be made of any suitable materials that are rigid and robust enough to support the entire screen 104. For example, the body 102 may be made of wood, plastics or metallic materials.

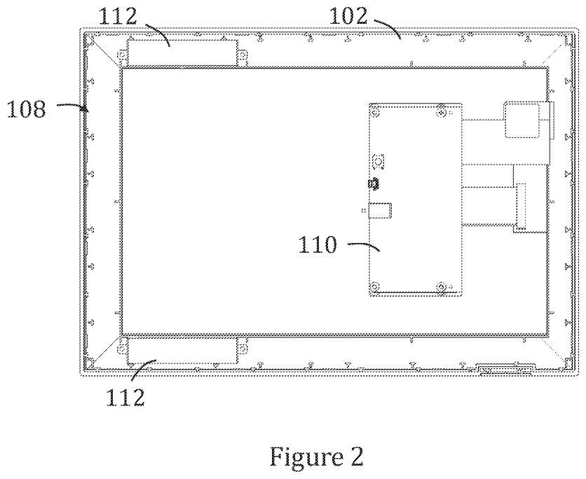

Referring to FIG. 2, the photo frame 100 also includes an electronic operating circuit 108 provided in the body 102 and adapted to process the digital content and control the screen 104 to display the digital content. The electronic operating circuit 108 includes a printed circuit board assembly (PCBA) 110 for controlling various electronic components of the electronic operating circuit 108, for example, two speakers 112 with audio capability in synchronization with the displayed video image. In the illustrated embodiment, the two speakers 112 are positioned around the periphery of the body 102 proximate to a vent (as will be discussed below), for playing and emitting an audio component of the digital content through the vent. The speakers 112 are preferably provided with dedicated sound processing and amplification.

The electronic operating circuit 108 further includes at least one microphone (not shown), e.g. two microphones or an array of microphones, positioned proximate to the vent for receiving an audio signal through the vent to control operation of the photo frame 100. The microphone is preferably provided with dedicated sound processing engine.

The electronic operating circuit controls the electronic display when the audio signal received by the microphone matches or satisfies a predetermined condition, as determined by the PCBA 110 using the data containing control instructions stored in a memory of the electronic operating circuit.

In one example embodiment, the audio signal is a user input signal, e.g. a voice command signal or a sound command signal such as claps, clicks, whistles from the user. The user input signal includes instructions to modify a mode and/or setting of the photo frame 100, such as instructions to activate a slideshow mode or deactivate a sleep mode, fast-forward a video, increase the volume of a video, etc.

For example, if the user desires to increase the volume of a video, the user may issue a voice command by saying “LOUDER”. In response to the voice command signal being received by the microphone, the PCBA 110 compares the signal with the data stored in the memory, determines the instruction corresponding to the signal based on the comparison, and in turn controls the speakers 112 to turn up the volume. Other example voice commands may include “SLIDESHOW”, “WAKE UP”, “FAST-FORWARD”, etc.

In another example embodiment, the audio signal is an ambient noise signal that is continuously received by the microphone. A sound pressure level or noise level of the ambient noise signal is used to modify a mode and/or setting of the photo frame 100, such as to enter a sleep mode or to wake up from a sleep mode, based on a comparison with a predetermined threshold stored in the memory. Preferably, the memory stores two different predetermined thresholds, e.g. 10 dB and 30 dB, corresponding to entering a sleep mode (e.g. with the screen 104 off) and waking up from a sleep mode (e.g. with the screen 104 on) respectively.

For example, during inactivity in a room, the ambient noise signal received by the microphone has a low noise level. The PCBA 110 may analyze the noise level and determine that the noise level reaches, i.e. is at or below, 10 dB, and in turn controls the photo frame 100 to enter sleep mode. The PCBA 110 may further determine that the noise level has maintained at or below the threshold for a predetermine period of time (e.g. 10 minutes) before controlling the photo frame 100 to enter sleep mode. As another example, when the photo frame 100 has entered sleep mode, upon receiving an ambient noise signal with a noise level of 30 dB or above by the microphone, the PCBA 110 may control the photo frame 100 to wake up from the sleep mode.

The electronic operating circuit 108 preferably further includes a wireless receiver, such as in particular a Wi-Fi module, for receiving digital content from a remote source (e.g. cloud), a memory (e.g. non-volatile memory) for storing the received digital content, and an image processor for processing the received digital content to be displayed on the screen 104.

During operation, the user may send or upload photos and videos from a smartphone to a cloud using a mobile application (app) installed on the smartphone, e.g. a dedicated app or any other supported apps such as a social media app. The digital contents may alternatively be uploaded via email. These photos and videos may then be retrieved from the cloud using the wireless receiver. Upon receiving the photos and videos and storing them in the memory of the electronic operating circuit 108, the stored photos and videos may be displayed directly on the screen 104 after being processed by the image processor. Alternatively, the photos and videos may be processed and stored in the memory in the form of a playlist that may be displayed in the future without repeating the uploading and retrieving processes.

The electronic operating circuit 108 may also include a wireless transmitter (e.g. as part of the Wi-Fi module) for communicating data and signals to a remote device (e.g. a smartphone). For example, the wireless transmitter may transmit an identification signal of the photo frame 100 to a smartphone, allowing a wireless connection between the photo frame 100 and the smartphone, thereby permitting the electronic operating circuit 108 of the photo frame 100 to access the cloud associated with the smartphone. The wireless communication may also allow the smartphone to control the photo frame 100 and to manage the settings of the photo frame 100, e.g. to adjust the brightness of the screen 104. Such wireless technology may include, apart from Wi-Fi, Bluetooth or Near Field Communication (NFC) technologies.

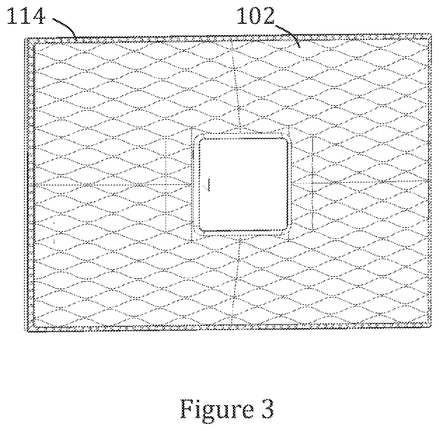

Referring to FIGS. 3 to 5, the body 102 of the photo frame 100 includes a vent 114 disposed at regular intervals around the entire periphery of the body, to which the speakers 112 are disposed proximate.

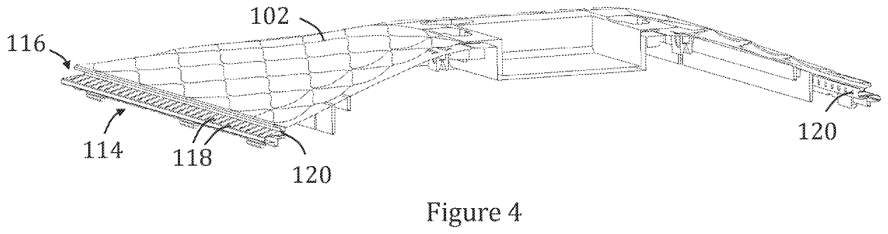

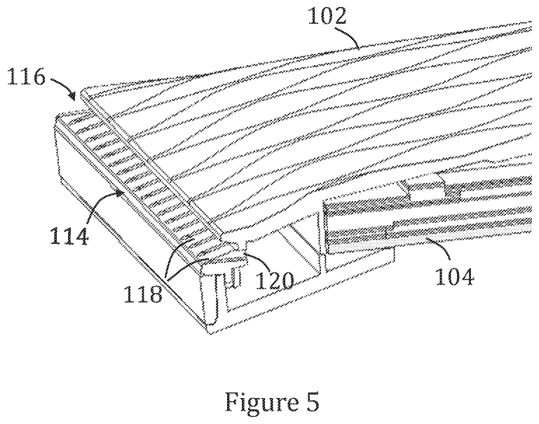

As better shown in FIGS. 4 and 5, the vent 114 is configured to be in communication with the ambient, i.e. external of the photo frame 100, for dissipation of heat generated by the electronic operating circuit 108. The vent 114 includes a groove 116, through which the vent 114 is in communication with the ambient, and a plurality of wedge-shaped spacers 118 each extending across opposite sides of the groove 116 to form a through-hole 120 between adjacent spacers 118 of each pair of spacers 118. The plurality of through-holes 120 are separated by the spacers 118, and in particular adjacent through-holes 120 of each pair of through-holes 120 are separated by a respective spacer 118. The through-holes 120 provide communication between interior of the body 102 accommodating the electronic operating circuit 108 and the ambient for heat dissipation.

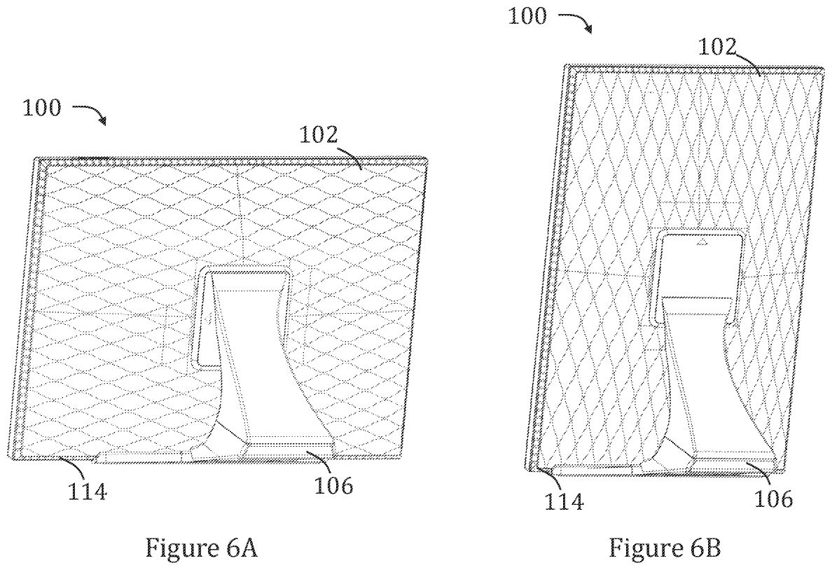

Referring to FIGS. 6A and 6B, the vent 114, particularly the groove 116, is also configured to be engageable with the stand 106 for the stand 106 to support the body 102 on a surface in two different orientations, such as a landscape orientation (FIG. 6A) and a transverse, portrait orientation (FIG. 6B). The back of the body 102, thus the screen 104, are preferably supported at an acute angle relative to the surface for a desired viewing angle of the screen 104.

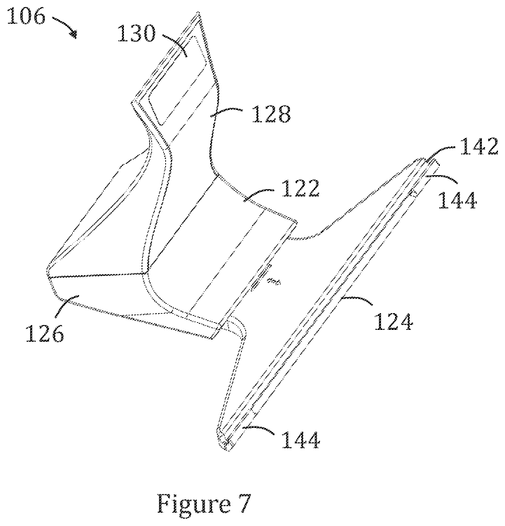

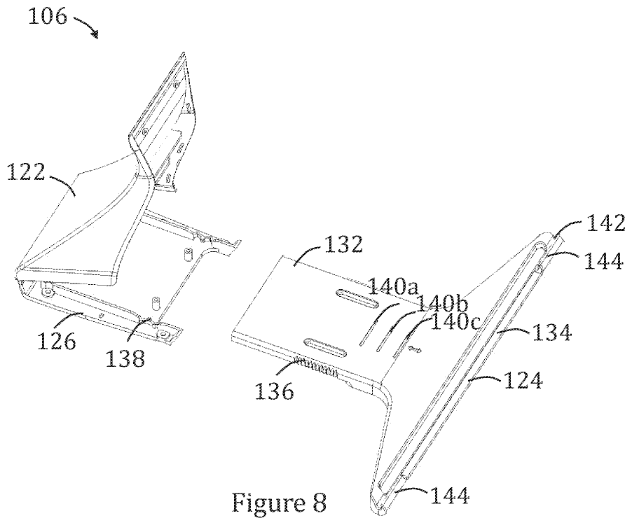

FIGS. 7 and 8 show the stand 106 of the photo frame 100, which provides adequate support for the photo frame body 102 to withstand the force of the finger of a user touch-sensing on the screen 104, hence remaining stationary. The stand 106 has a substantially L-shape, with an upper limb of the L-shape being inclined forward at an acute angle less than 90°, e.g. 70°, to a horizontal lower limb of the L-shape. The stand 106 is formed by an upper part 122 for contact with the back of the body 102 and a lower part 124, which is releasably coupled to the upper part 122, for resting on the table top. The upper and lower parts 122, 124 of the stand 106 are separable from each other, such that they can be packed closer together when separated to reduce the storage space required, and this is particularly advantageous for transportation of the photo frame 100.

The upper part 122 is provided with, at an upper end thereof, a frictional gripping element 130 (e.g. a rubber pad) for contact with the back of the body 102 to enhance the support and stability of the photo frame 100 relative to the stand 106. Additional frictional gripping elements 131 are provided on the undersides of the upper and lower parts 122, 124 (FIG. 1) for contact with the table top, thereby further improving the stability of the photo frame 100.

The upper part 122 is of a substantially L-shape, having a toe 126 from which the lower part 124 extends in the same direction on generally the same plane. The lower part 124 is oriented transversely to a substantially vertical main portion 128 of the L-shaped upper part 122, together forming the L-shaped stand 106 with a forwardly-extended bottom.

The lower part 124 is of a substantially T-shape, having a smaller or narrow rear end 132 inserted into the toe 126 of the L-shaped upper part 122 and an enlarged or widened front end 134 for engaging the groove 116 of the vent 114 to support the body 102 of the photo frame 100. The rear end 132 includes a pair of parallel, partially serrated edges with a row of recesses 136. The recesses 136 are engageable with spring-loaded protrusions 138 provided within the toe 126 to maintain the extent to which the lower part 124 extends from the upper part 122, and in turn the angle of the body 102 relative to the table top. With aids of these inter-engageable elements between the upper and lower parts 122, 124, i.e. the protrusions 138 and the recesses 136, various viewing angles of the screen 104 can be achieved as desired.

The lower part 124 is further provided with indicators (e.g. three indicators 140a, 140b, 140c in the illustrated embodiment) for indicating to the user the extent to which the lower part 124 extends from the upper part 122, which determines the tilted or viewing angle of the screen 104 relative to the surface on which the photo frame 100 is supported.

The lower part 124 and the toe 126 of the upper part 122 together forms a relatively large footprint that enhances the stability of the stand 106 and in turn the photo frame body 102 thus the screen 104 in use, particularly when the user operates through touch-sensing the screen 104.

The widened front end 134 of the lower part 124 is provided with a slot 142 for receiving the edge of the photo frame body 102 and specifically the rear side of opposite sides of the groove 116 of the vent 114 along the edge of the body 102. In the illustrated embodiment, the slot 142 extends across the entire horizontal edge or length of the widened front end 134 for stable support of the body 102 of the photo frame 100. The slot 142 is partially defined by two projections 144 which are positioned at opposite ends of the horizontal edge of the front end 134. Each of the projections 144 has a width extending along a portion of the horizontal edge that in turn extends along a portion of the periphery of the body 102, with which the projection 144 engages.

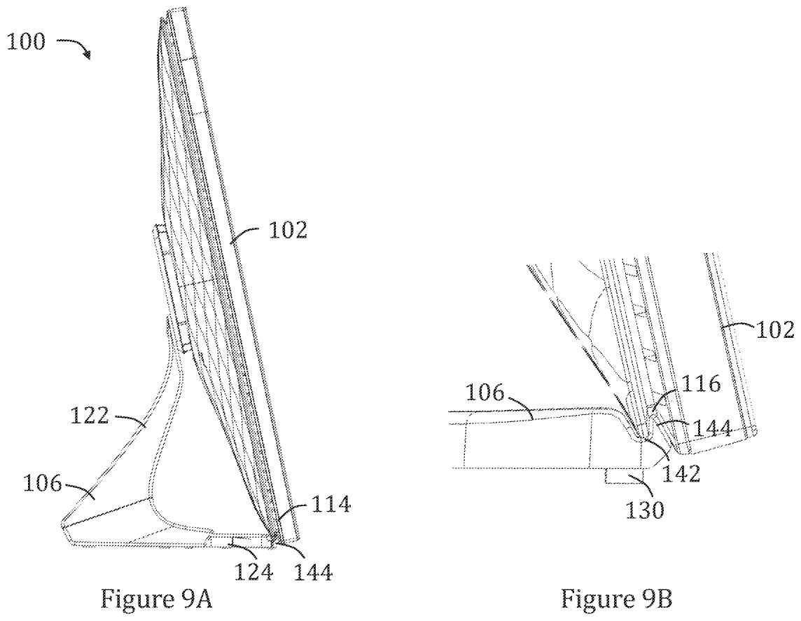

FIGS. 9A and 9B show the engagement between the body 102 of the photo frame 100 and the stand 106. The projections 144 of the stand 106 are insertable into (e.g. hooked into) the groove 116 of the vent 114 for engagement therewith, while the rear side of the groove 116 is received in the slot 142 of the stand 106. In the illustrated embodiment, the projections 144 and the groove 116 of the vent 114 have complementary shapes in terms of cross-section. The projections 144 are inclined slightly inwards and towards the upper part 122 of the stand 106, having a cross-section complementary to the cross-section of the groove 116 which is partially defined by the wedge-shaped spacers 118. This design results in fitting engagement between the photo frame 100 and the stand 106.

The present invention, as discussed above, provides an electronic display with an improved vent over the pre-existing electronic displays. The multi-functional vent in the described embodiment of the present electronic display is capable of not only dissipating heat, but also emitting sound and engaging with a stand for stable support of the body of the electronic display in different orientations. In addition, the extendable stand of the present electronic display not only provides a large footprint for improved support and stability, but also enables user adjustment of the viewing angle of the screen as desired.

It will be appreciated by persons skilled in the art that numerous variations and/or modifications may be made to the invention as shown in the specific embodiments without departing from the spirit or scope of the invention as broadly described.

The arrangement and configuration of the electronic operating circuit may be different from that illustrated. Although two speakers are shown, the electronic operating circuit may include only one speaker or an array of speakers. The speakers may be provided without dedicated sound processing and amplification. The microphones may be provided without dedicated sound processing engine. The user input signal, instead of or in addition to the ambient noise signal, may be compared with the predetermined thresholds of sound pressure levels to control operation of the electronic display.

The structure of the vent may be different from that illustrated. For example, instead of being disposed at regular intervals around the entire periphery of the body, the vent may be disposed partially around the periphery of the body, or disposed continuously around the periphery (either the whole or a part thereof) of the body. It would be advantageous to include a vent that is disposed at at least two portions of the periphery, with which the stand is engageable to support the body in two different orientations, e.g. landscape and portrait orientations.

In addition, the structure of the stand may be different from that illustrated. The projections that are insertable into the groove of the body may be extend along the entire horizontal edge of the enlarged end of the lower part of the stand, to further improve the stability of the electronic display. The inter-engageable elements on the separable upper and lower parts of the stand may utilize configurations other than protrusions and recesses. The upper and lower parts may be fixedly coupled to each other or integrally formed.

The described embodiments of the invention should therefore be considered in all respects as illustrative, not restrictive.

1. An electronic display comprising:
a body;
an electronic display panel supported by the body and comprising a screen for displaying digital content; and
an electronic operating circuit provided in the body and adapted to process said digital content and control the screen to display said digital content;
wherein the body includes:
a vent disposed at least partially around a periphery of the body, the vent being configured to be in communication with the ambient for dissipation of heat generated by the electronic operating circuit, and to be engageable with a stand for the latter to support the body on a surface.

2. The electronic display according to claim 1, wherein the vent is disposed around the entire periphery of the body.

3. The electronic display according to claim 2, wherein the vent is disposed continuously around the entire periphery of the body.

4. The electronic display according to claim 2, wherein the vent is disposed at regular intervals around the entire periphery of the body.

5. The electronic display according to claim 1, wherein the vent is configured to engage with the stand for supporting the body in a first orientation and a different second orientation.

6. The electronic display according to claim 5, wherein the vent is disposed at at least two, first and second portions of the periphery of the body, with which first and second portions the stand is engageable to support the body in the first orientation and the second orientation respectively, the first and second orientations being transverse to each other.

7. The electronic display according to claim 1, wherein the vent includes a groove, through which the vent is in communication with the ambient.

8. The electronic display according to claim 7, wherein the groove is engageable with the stand.

9. The electronic display according to claim 7, wherein the vent further includes a plurality of through-holes, with adjacent through-holes of each pair being separated by a respective spacer.

10. The electronic display according to claim 9, wherein the spacers extend across opposite sides of the groove to form a said through-hole between adjacent spacers of each pair, the through-holes providing communication between interior of the body and the ambient.

11. The electronic display according to claim 1, wherein the electronic operating circuit includes at least one speaker for playing and emitting an audio component of said digital content through the vent.

12. The electronic display according to claim 11, wherein said at least one speaker is located proximate to the vent.

13. The electronic display according to claim 1, wherein the electronic operating circuit includes at least one microphone for receiving an audio signal through the vent to control operation of the electronic display.

14. The electronic display according to claim 13, wherein said at least one microphone is located proximate to the vent.

15. The electronic display according to claim 13, wherein the electronic operating circuit is adapted to control the electronic display when said received audio signal matches a predetermined condition.

16. The electronic display according to claim 15, wherein the predetermined condition comprises determination of said received audio signal including instructions to modify a setting of the electronic display.

17. The electronic display according to claim 15, wherein the predetermined condition comprises determination of a sound pressure level of said received audio signal reaching a predetermined threshold.

18. The electronic display according to claim 17, wherein the electronic operating circuit is adapted to control the electronic display to enter a sleep mode in response to determining that said sound pressure level is at or below said predetermined threshold.

19. The electronic display according to claim 1, wherein the screen is touch-sensitive.

20. The electronic display according to claim 1, further including a said stand for supporting the body on a surface, at an acute angle thereto.

21. The electronic display according to claim 20, wherein the stand comprises a projection insertable into the vent for engagement with the vent.

22. The electronic display according to claim 20, wherein the stand comprises an upper part for contact with a back of the body and a lower part coupled to the upper part and configured to be engageable with the vent.

23. The electronic display according to claim 22, wherein the lower part of the stand includes a or the projection for engagement with the vent, the projection having a width that extends along a portion of the periphery of the body, with which portion the projection engages.

24. The electronic display according to claim 23, wherein the lower part of the stand is oriented transversely to the upper part.

25. The electronic display according to claim 22, wherein the lower part of the stand is extendable from the upper part for adjusting the angle of the body relative to the surface.

26. The electronic display according to claim 25, wherein the stand includes inter-engageable elements on the upper and lower parts of the stand for engagement to maintain the extent to which the lower part extends from the upper part and in turn the angle of the body relative to the surface.

27. The electronic display according to claim 26, wherein the inter-engageable elements comprise a protrusion and a row of recesses on the upper and lower parts of the stand, with one of which recesses the protrusion is engageable to maintain the angle of the body relative to the surface.

28. The electronic display according to claim 22, wherein the upper part of the stand includes a frictional gripping element for contact with the back of the body.

29. The electronic display according to claim 22, wherein the upper part and the lower part of the stand are separable apart.
